(19) United States
(12) Patent Application Publication
(10) Pub. No.: US 2013/0187640 A1
(43) Pub. Date: Jul. 25, 2013

(54) MULTIPOLAR ENCODER FOR POSITION SENSORS, AND DETECTION DEVICE INCLUDING SUCH AN ENCODER COMBINED WITH AT LEAST ONE POSITION SENSOR

(71) Applicant: Jérôme Corona, Bron (FR)

(72) Inventor: Jérôme Corona, Bron (FR)

(73) Assignee: ELECTRICFIL AUTOMOTIVE, MIRIBEL CEDEX (FR)

(21) Appl. No.: 13/057,163

(22) PCT Filed: Jul. 29, 2009
(86) PCT No.: PCT/FR2009/051523

§ 371 Date: Mar. 30, 2011

(30) Foreign Application Priority Data
Aug. 12, 2008 (FR) 0855547

(51) Int. Cl. G01B 7/30; G01R 33/09

(52) U.S. Cl. CPC G01B 7/30; G01R 33/093
USPC 324/207.21; 324/207.11; 324/207.25

(57) ABSTRACT

A position sensor coder of the type comprising a multipolar magnetic annulus (2) provided at its circumference with poles having polarities of opposite signs, the coder including at least one mark zone (Pi) presenting an angular width (Li) greater than the angular width of each of the alternating poles situated outside said zone around the circumference of the annulus, the coder being characterized in that said mark zone (Pi) comprises two adjacent singular poles (Ni, Si) presenting polarities of opposite signs and placed in the continuity of pole alternation in the annulus (2) and of angular width that is greater than the angular width of the poles lying outside the mark zone, the magnetization within the singular poles varying gradually in continuous manner between the two ends of the mark zone.

The present invention relates to the technical field of detecting the movements and positions of elements within mechanical systems. The invention relates in particular to the field of magnetic detector devices including a coder element that moves close to a detector sensor or cell and that is adapted to detect the position and/or the speed of a movable target in the general sense.

More particularly, the invention relates to providing a magnetic coder fitted with a series of north poles and south poles mounted in alternation to act as a magnetic target for a detector cell of the differential giant magnetoresistance (GMR) type.

A particularly advantageous application for the invention lies in the automotive field where the sensor can be used in the context of injection functions, for example.

In the state of the art, various types of sensor are known that are suitable for delivering information corresponding to the position of the movable target. Traditionally, such a sensor co-operates with a movable target made, for example, out of soft magnetic material and presenting at least one tooth, and more generally a series of teeth that are spaced apart by gaps. Such a sensor also has a permanent magnet defining an airgap with the movable target. A probe is placed in the airgap, which probe is sensitive to the direction and the intensity of magnetic induction.

On each pass of a tooth in front of the probe, movement of the movable target gives rise to a variation in the magnetic induction passing through the probe, and thus delivers an electric signal as a function of the direction and the amplitude of the magnetic induction. The sensitive probe is associated in particular with a level comparator presenting hysteresis, and delivering an output that takes a first logic state when the electric signal delivered by the probe is greater than a predetermined threshold and a second logic state when the electric signal is less than a predetermined threshold.

The drawback of such a sensor is its sensitivity to variation in parameters such as the temperature and the size of the airgap between the target and the sensor.

In the state of the art, it is also known to use a position or speed sensor device that includes a magnetic coder moving past a detector cell. Such a coder is constituted by a multipole magnetic annulus provided on its circumference with alternating north poles and south poles. However, the drawback of such a sensor is its great sensitivity to variation in the size of the airgap between the measurement cell and the coder.

Magnetic coders are also known that include a zone of singular peripheral magnetization, i.e. a mark zone. That singular zone traditionally comprises a magnetic pole of angular width that is greater than the angular width of the other poles of the coder. The wider magnetic pole gives rise to variation in the period and the amplitude of the signal output by the detector cell and that is used as a switching or reference signal for determining the rotary position of the element on which the coder is fastened. Nevertheless, such coders present the same drawback of sensitivity to variation in the size of the airgap as the previously-mentioned coders, and thus great sensitivity to the noise generated by the mechanical system within which the coder and the position sensor are incorporated.

In order to reduce those problems, proposals have been made, in particular by the Applicant in applications FR 2 895 075 A1 and FR 2 901 019 A1, or indeed in application U.S. Pat. No. 5,523,679, to magnetize the pole forming the singular zone of the coder in gradual manner between its two ends. Such gradual magnetization serves in particular to reduce significantly the disturbances in the output signal from the detector cell of the sensor that are associated with noise. Nevertheless, those coders use a Hall effect measurement cell and they do not implement GMR cells, so they cannot comply with the common periods of present standards in the automobile field (6°/18°/6° in and around the zone). Furthermore, the weight of that pole, even when gradually magnetized, is always much stronger than the contribution of the adjacent poles, thereby preventing period stability over the range of airgap sizes.

Still for this purpose, another solution is proposed in document EP 0 611 952 A1, that consists in providing a magnetic coder having a singular zone with two poles that are strongly magnetized, respectively a north pole and a south pole, and that are separated from each other by a zone with little or no magnetization. Nevertheless, such a coder continues to provide an output signal in which the switching zone is extensive, thereby degrading the accuracy of the detector device. Furthermore, a coder having a zone within the mark zone with little or no magnetization tends to produce unbalance between the two magnetic poles of the mark zone and the poles outside said zone, thereby preventing stability in the electric front in the middle of the zone, and preventing stability in the periods over the range of airgap sizes.

The object of the invention is thus to remedy the drawbacks of the state of the art by proposing a coder for a position and/or speed sensor that is relatively insensitive to variation in airgap size, while being suitable for delivering a working signal that presents good measurement accuracy.

To solve these various problems, the present invention firstly provides a position sensor coder of the type comprising a multipolar magnetic annulus provided at its circumference with poles having polarities of opposite signs that are placed in alternating manner and that are designed to travel past a measurement cell that delivers a differential periodic signal corresponding to the variation in the intensity of the magnetic field delivered by the poles. This coder includes, in known manner, at least one mark zone presenting an angular width greater than the angular width of each of the alternating poles situated outside said zone around the circumference of the annulus.

In characteristic manner, the mark zone comprises two adjacent singular poles presenting polarities of opposite signs that are placed in the continuity of pole alternation in the annulus and that are of angular width that is greater than the angular width of the poles lying outside the mark zone, the magnetization within the singular poles varying gradually in continuous manner between the two ends of the mark zone.

In accordance with a first preferred characteristic of the invention, the junction between the two singular poles is situated in the middle of the angular width covered by the mark zone.

Furthermore, in accordance with another advantageous characteristic of the coder of the invention, the gradual magnetization of the singular poles follows variation that increases or decreases, which variation may be selected to be substantially linear or indeed to follow a curve.

Still according to the invention, the magnetic poles situated on either side of the mark zone also present, and in advantageous manner, a varying angular width less than the angular width of the singular poles in the mark zone.

More particularly, the angular width of the mark zone lies in the range 15° to 20°, and the angular width of the magnetic poles outside the mark zone lies in the range 2° to 8°.

In a second aspect, the present invention also provides a position detector device for detecting a position of a movable member, in particular in rotary movement, the device being characterized in that it includes at least one coder, as defined above, that is secured to said movable member, and at least one measurement cell that delivers a periodic differential electric signal corresponding to the variation in the intensity of the magnetic field generated by the poles of said coder.

In preferred and advantageous manner, the measurement cell of the position detector device of the invention is selected to be a cell of the GMR (“giant magnetoresistance”) type.

Finally, the invention also provides a method of detecting the position of a movable member moving in rotation, wherein said movable member is fitted with a coder as described above and wherein the variation in the magnetic field generated by the poles of said coder is detected and measured by means of a measurement cell delivering a differential periodic signal of intensity that varies in accordance with the variation in the magnetic field generated by the poles of the coder following the movement and the position of the movable member, the measurement cell advantageously being a cell of the GMR (giant magnetoresistance) type.

Various other characteristics appear from the following description made with reference to the accompanying drawings that show embodiments of the invention as non-limiting examples.

In the accompanying figures:

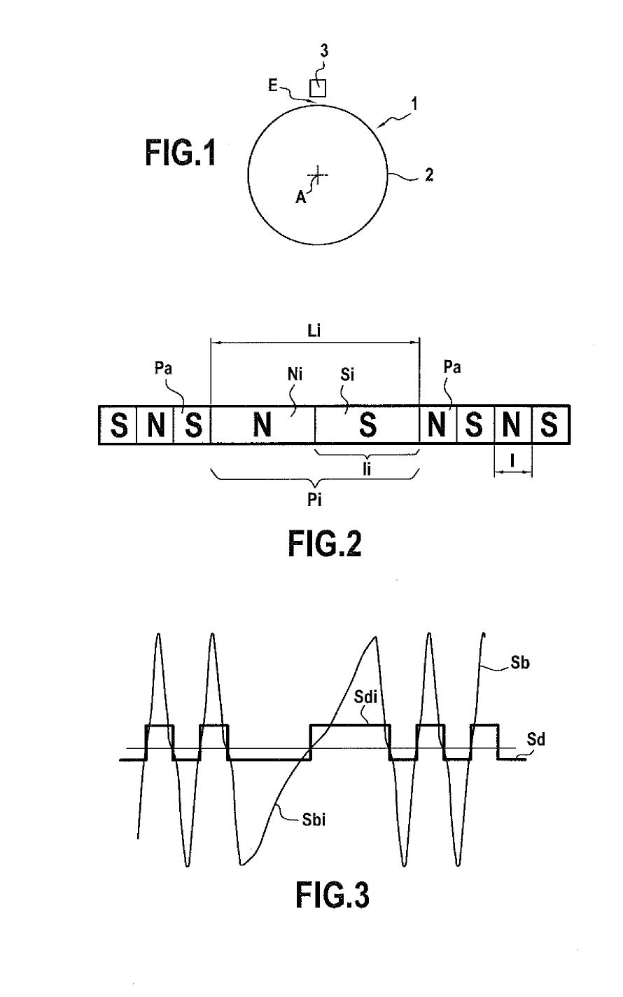

FIG. 1 is a diagrammatic plan view showing an example of an embodiment of a position detector device in accordance with the invention;

FIG. 2 is a view unrolled in a plane of an example embodiment of coder in accordance with the invention; and

FIG. 3 shows the variation in the differential magnetic signal obtained when a coder of the invention goes past a GMR detector cell, and also shows the digital signal obtained from the differential electrical output signal from the cell.

FIG. 1 shows an embodiment of a position detector device 1 comprising a magnetic coder 2 mounted to move past at least one magnetic position sensor or cell 3. The coder 2 is constituted in the form of a multipolar magnetic annulus that is driven in rotation about its center, about an axis A, and that is provided on its circumference with alternating north and south poles N and. S presenting magnetization that is preferably radial. For example, the coder 2 is constituted by a support-forming ring having an elastomer band bonded thereto, the elastomer being filled with magnetized particles to constitute the north and south poles N and S.

The measurement cell 3 delivers a periodic differential magnetic signal Sb corresponding to the variation in the intensity of the magnetic field delivered by the poles moving past it. In accordance with the invention, this detector cell 3 is a differential GMR cell (a giant magnetoresistance cell). The measurement cell 3 is connected to processor means (not shown but known in themselves) that enable a digital output signal Sd to be obtained, which in this example is a squarewave signal.

In the example shown, the coder 1 has a series of south poles S and north poles N that are arranged to present a regular spacing pitch between pairs of adjacent poles. For example, the angular width l of each regular pole is 3°. As can be seen more clearly in FIG. 2, the coder 1 also has at least one singular zone or mark Pi that presents, between two adjacent regular poles Pa, a spacing that is different from the regular spacing pitch between the south and north poles S and N outside said zone Pi. In the example shown, the mark zone Pi possesses an angular width Li of at least 18° and, in accordance with the invention, it comprises a singular north pole Ni and a singular south pole Si that are adjacent to each other and disposed in the continuity of alternating poles at the periphery of the coder 1. In the example shown, the singular north pole Ni is interposed between adjacent regular south pole Pa and the singular south pole Si, which is in turn adjacent to the regular north pole Pa. These singular poles Ni and Si are thus adjacent.

In comparison with the other north and south poles N and S of the coder that are regular, each of the singular poles Ni and Si presents an angular width that is much greater, and preferably as shown an angular width li that is about three times that of the regular north and south poles N and S, i.e. a width li that is substantially equal to 9°. For example, for coders having 60 minus two poles, the angular width Li of the mark zone Pi lies in the range 15 to 20° and the angular width l of the regular magnetic poles outside the mark zone lies in the range 2° to 8°. For a coder having 30 minus one poles, the angular width Li of the mark zone Pi lies in the range 15° to 40° and the angular width l of the regular magnetic poles outside the mark zone lies in the range 2° to 15°.

As can be seen in FIG. 3, the mark zone Pi of the coder of the invention serves to obtain a differential magnetic signal Sbi in this zone that, unlike the traditional signals obtained with prior art coders, presents a steep slope passing through 0 at a single point, exactly at the junction between the two poles Ni and Si of the mark zone Pi.

This has the positive consequence of the differential output signal from the detector cell 3 switching, i.e. passing through 0, likewise exactly in register with the junction between the two poles Ni and Si.

Thus the switching of the rising (or falling) front takes place in stable manner in the mark zone. This is found to be particularly advantageous since it enables the front to be used by the vehicle computer or indeed, when the coder of the invention is used with a bidirectional cell, it enables the zero-crossing point to be used to “trigger” direction recognition.

Finally, another advantage of the accurate switching between the poles Ni and Si of the mark zone lies in the good distribution obtained for the magnetic strength of these two poles over the total width of the mark zone, thereby avoiding excessive modulation of the general magnetic offset and consequently reducing inaccuracy in electrical switching depending on variation of the airgap.

Still according to the invention, each pole Ni, Si of the mark zone Pi presents an angular width li that is identical and substantially equal to 9°. Nevertheless, in order to further reduce the offset modulation created by the angular unbalance between the poles of the mark zone Pi and the poles lying outside said zone, corrective measures are implemented on the angular widths of the north and south poles N and S adjacent to the mark zone Pi.

Thus, if the mean angular width of the set of north and south poles N, S outside the mark zone Pi is about 3°, then the individual angular widths of each north and south pole N, S are, in fact, adjusted by a value E that varies firstly so as to reduce the influence of the poles Ni and Si of the mark zone, and secondly, for crank shaft applications in the automotive field in particular, so as to comply with the standard angle period widths in the electrical signal Sd output by the GMR measurement cell 3.

Furthermore, in order to stabilize the differential output signal Sd from the measurement cell 3, the poles Ni and Si of the mark zone Pi present, according to the invention, magnetization that is gradual between the ends of the mark zone Pi, such that the raw magnetic signal obtained by the poles Ni and Si passing in front of the measurement cell 3 varies symmetrically. In other words, the magnetization of the singular poles Ni and Si diminishes or increases constantly from one end to the other of the mark zone Pi.

This gradual magnetization of the poles in the mark zone Pi decreases going from the north pole Ni towards the south pole Si, or naturally increases going from the south pole Si to the north pole Ni. The decrease or increase in magnetization may vary in any way, even though variation that is linear or that follows a curve is preferred.

The invention is not limited to the examples described and shown since various modifications can be made thereto without going beyond the ambit of the invention.

1. A position sensor coder of the type comprising a multipolar magnetic annulus (2) provided at its circumference with poles having polarities of opposite signs that are placed in alternating manner and that are designed to travel past a measurement cell (3) that delivers a differential periodic signal corresponding to the variation in the intensity of the magnetic field delivered by the poles, the coder including at least one mark zone (Pi) presenting an angular width (Li) greater than the angular width of each of the alternating poles situated outside said zone around the circumference of the annulus, the coder being characterized in that said mark zone (Pi) comprises two adjacent singular poles (Ni, Si) presenting polarities of opposite signs and placed in the continuity of pole alternation in the annulus (2) and of angular width that is greater than the angular width of the poles lying outside the mark zone, the magnetization within the singular poles varying gradually in continuous manner between the two ends of the mark zone.

2. A position sensor coder according to claim 1, characterized in that the junction between the two singular poles (Ni, Si) is situated in the middle of the angular width covered by the mark zone (Pi).

3. A position sensor coder according to claim 1, characterized in that the gradual magnetization of the singular poles follows variation that decreases from the north pole (Ni) to the south pole (Si).

4. A position sensor coder according to claim 3, characterized in that the decreasing variation in the magnetization of the singular poles (Ni, Si) in the mark zone is substantially linear.

5. A position sensor coder according to claim 1, characterized in that the decreasing variation of the magnetization of the singular poles (Ni, Si) in the mark zone follows a curve.

6. A position sensor coder according to claim 1, characterized in that the magnetic poles (Pa) situated on either side of the mark zone (Pi) present a varying angular width less than the angular width of the singular poles (Ni, Si) in the mark zone.

7. A position sensor coder according to claim 1, characterized in that the angular width (Li) of the mark zone (Pi) lies in the range 15° to 20°, and the angular width of the magnetic poles outside the mark zone lies in the range 2° to 8°.

8. A position detector device (1) for detecting a position of a movable member, in particular in rotary movement, the device being characterized in that it includes at least one coder (2) in accordance with claim 1, secured to said movable member, and at least one measurement cell (3) delivering a periodic differential electric signal corresponding to the variation in the intensity of the magnetic field generated by the poles of said coder.

9. A position detector device (1) according to claim 8 for detecting the position of a movable member, the device being characterized in that the measurement cell (3) is of the GMR (“giant magnetoresistance”) type.

10. A method of detecting the position of a movable member moving in rotation, wherein said movable member is fitted with a coder (2) in accordance with claim 1 and wherein the variation in the magnetic field generated by the poles of said coder is detected and measured by means of a measurement cell (3) delivering a differential periodic signal of intensity that varies in accordance with the variation in the magnetic field generated by the poles of the coder following the movement and the position of the movable member.
